(19) United States
(12) Patent Application Publication
(10) Pub. No.: US 2020/0407634 A1
(43) Pub. Date: Dec. 31, 2020

(54) LIGHT EMITTING DEVICE AND METHOD OF MANUFACTURING LIGHT EMITTING DEVICE

(71) Applicant: NICHIA CORPORATION, Anan-shi (JP)

(72) Inventors: Shigeyuki SUZUKI, Tokushima-shi (JP); Atsushi KOJIMA, Tokushima-shi (JP); Hiroyuki WATANABE, Itano-gun (JP); Shoji HOSOKAWA, Tokushima-shi (JP)

(73) Assignee: NICHIA CORPORATION, Anan-shi (JP)

(21) Appl. No.: 16/912,689

(22) Filed: Jun. 25, 2020

(30) Foreign Application Priority Data
Jun. 26, 2019 (JP) 2019-118199
Oct. 30, 2019 (JP) 2019-197966

(51) Int. Cl. C09K 11/77; H01L 33/50; C09K 11/08

(52) U.S. Cl. CPC C09K 11/7734; H01L 2933/0041; C09K 11/0883; H01L 33/502

(57) ABSTRACT

A light emitting device includes a light emitting element that emits light having a peak emission wavelength in a range of 365 to 500 nm, and a fluorescent member containing a resin and a fluorescent material having a composition represented by CaₛSrₜEuᵤSiᵥAl_{w}Nₓ wherein 0.05≤s≤0.995, 0≤t≤0.95, 0.005≤u≤0.04, 0.8≤s+t+u≤1.1, 0.8≤v≤1.2, 0.8≤w≤1.2, 1.8≤v+w≤2.2, and 2.5≤x≤3.2, and configured to be excited by the light from the light emitting element to emit light having a peak emission wavelength in a range of 620 to 670 nm. A content of the fluorescent material in the fluorescent member is in a range of 115 to 150 parts mass relative to 100 parts mass of the resin. The light emitting device is configured to emit light having a dominant wavelength in a range of 610 to 630 nm.

### CROSS-REFERENCE TO RELATED PATENT APPLICATIONS

The present application claims priority under 35 U. S. C. § 119 to Japanese Patent Applications No. 2019-118199, filed Jun. 26, 2019 and No. 2019-197966, filed Oct. 30, 2019. The contents of Japanese Patent Applications No. 2019-118199 and No 2019-197966 are incorporated herein by reference in their entirety.

### BACKGROUND

### Technical Field

The present disclosure relates to a light emitting device and a method of manufacturing the light emitting device.

### Description of Related Art

In present years, light emitting diodes (LEDs) have been widely used as light emitting elements with high energy-serving properties. For example, LEDs to emit monochromatic red light have been used for stop lamps etc., in the field of on-vehicle.

For example, WO 2014/125714A discloses a light emitting device configured to emit red light, which includes a light element to emit light in a range of ultraviolet light to blue light and a fluorescent material to absorb light from the light emitting element and convert the wavelength of the light.

### SUMMARY

Such a light emitting device employing a combination of a light emitting element and a fluorescent material to emit red light has been required a further improvement in its luminous flux and excitation purity.

Accordingly, an object of the present disclosure is to provide a light emitting device configured to emit red light with high luminous flux and high excitation purity, and a method of manufacturing the light emitting device.

The present disclosure includes embodiments as illustrated below.

A light emitting device according to a first embodiment of the present disclosure includes a light emitting element that emits light having a peak emission wavelength in a range of 365 to 500 nm, a fluorescent member including a resin and a fluorescent material configured to be excited by light from the light emitting element and to emit light with a peak emission wavelength in a range of 620 to 670 nm and having a composition represented by a formula (I): CaₛSrₜEuᵤSiᵥAl_{w}Nₓ (I). In the formula (I), s, t, u, v, w, and x respectively satisfy 0.05≤s≤0.995, 0≤t≤0.95, 0.005≤u≤0.04, 0.8≤s+t+u≤1.1, 0.8≤v≤1.2, 0.8≤w≤1.2, 1.8≤v+w≤2.2, and 2.5≤x≤3.2. A content of the fluorescent material in the fluorescent member is in a range of 115 to 150 parts mass relative to 100 parts mass of the resin, such that the light emitting device is configured to emit light having a dominant wavelength in a range of 610 to 630 nm.

A light emitting device according to a second embodiment of the present invention includes a light emitting element that emits light having a peak emission wavelength in a range of 365 to 500 nm and a fluorescent member containing a resin and a fluorescent material to be excited by light from the light emitting element to emit light having a peak emission wavelength in a range of 620 to 670 nm, the fluorescent material having a composition represented by the formula (I). When a peak emission wavelength in an emission spectra of the light emitting device is indicated as λe_{P} and a peak emission wavelength in an emission spectra of the fluorescent material is indicated by λf_{P}, a wavelength difference λe_{P}−λf_{P} is equal to or greater than 8 nm, and light emitted from the light emitting device has a dominant wavelength in a range of 610 to 630 nm.

A method of manufacturing a light emitting device according to a third embodiment of the present invention includes disposing a light emitting element that emits light having a peak emission wavelength in a range of 365 to 500 nm on a support member, providing a fluorescent material and a resin, the fluorescent material having a composition represented by the formula (I) and configured to be excited by the light from the light emitting element to emit light having a peak emission wavelength in a range of 620 to 670 nm,

CaₛSrₜEuᵤSiᵥAl_{w}Nₓ (I)

(In the formula (I), s, t, u, v, w, and x respectively satisfy 0.05≤s≤0.995, 0≤t≤0.95, 0.005≤u≤0.04, 0.8≤s+t+u≤1.1, 0.8≤v≤1.2, 0.8≤w≤1.2, 1.8≤v+w≤2.2, and 2.5≤x≤3.2), mixing the fluorescent material and the resin such that a content of the fluorescent material is in a range of 115 to 150 parts mass relative to 100 parts mass of the resin to obtain a composition for fluorescent member, disposing the composition for fluorescent member on the light emitting element to obtain a fluorescent member, to obtain a light emitting device to emit light having a dominant wavelength in a range of 610 to 630 nm.

According to certain embodiments of the present invention, a light emitting device that can emit red light with a high luminance and high excitation purity, and a method of manufacturing the light emitting device can be provided.

### BRIEF DESCRIPTION OF THE DRAWINGS

FIG. 1 is a schematic cross-sectional view of a light emitting device according to an embodiment of the present invention.

FIG. 2 is a diagram showing reflection spectra of the fluorescent materials 1 to 3 used in the light emitting devices of certain embodiments of the present invention.

FIG. 3 is a diagram showing emission spectra of the light emitting devices according to Example 1, Comparative Examples 1 and 2 and emission spectra of the fluorescent material 2 and a single particle of the fluorescent material 2.

FIG. 4 is a diagram showing emission spectra of the light emitting devices according to Example 2 and Comparative Example 2, and emission spectra of the fluorescent material 3 and a single particle of the fluorescent material 3.

FIG. 5 is a SEM image showing a portion of a cross-section of a light emitting devices according to Example 1.

FIG. 6 is a SEM image showing a portion of a cross-section of a light emitting devices according to Comparative Example 1.

FIG. 7 is a SEM image showing a portion of a cross-section of a light emitting devices according to Comparative Example 2.

### DETAILED DESCRIPTION

Hereinafter, embodiments of light emitting devices according to a method of manufacturing the present invention will be described. The preferred embodiments are intended as illustrative of light emitting devices a method of manufacturing to give concrete forms to technical ideas of the present invention, and the scope of the invention is not limited to those described below. The relation between the color names and the chromaticity coordinates, the relation between the range of wavelength of light and the color name of single-color light, and the like conform to JIS Z8110. Further, the “content of each component in the composition” indicates that in the case where a plural number of substances corresponding to each component are present in the composition, refers to a total amount of the plural number of substances in the composition.

### Light Emitting Device

A light emitting device according to a first embodiment or a second embodiment includes a light emitting element having a peak emission wavelength in a range of 365 to 500 nm and a fluorescent member containing a fluorescent material to be excited by light from the light emitting element to convert an wavelength of the light to emit light having a peak emission wavelength in a range of 620 to 670 nm, the fluorescent material having a composition represented by a formula (I) shown below.

CaₛSrₜEuᵤSiᵥAl_{w}Nₓ (I)

(In the formula (I), s, t, u, v, w, and x respectively satisfy 0.05≤s≤0.995, 0≤t≤0.95, 0.005≤u≤0.04, 0.8≤s+t+u≤1.1, 0.8≤v≤1.2, 0.8≤w≤1.2, 1.8≤v+w≤2.2, and 2.5≤x≤3.2.)

The fluorescent member includes the fluorescent material and the resin. The content of the fluorescent material in the fluorescent member may be in a range of 115 to 150 parts mass to the content of the resin as 100 parts mass. Further, the light emitting device is configured to emit light having a dominant wavelength in a range of 610 to 630 nm. The dominant wavelength is determined according to JIS Z8701, in which assuming a straight line passing through chromaticity coordinates (x=0.3333, y=0.3333) of white light and chromaticity coordinates (x, y) (whereinafter may be referred to as “a chromaticity point”) of emission color of the light emitting device of CIE (Commission international de l'eclairage) 1931 chromaticity diagram, the wavelength of an intersection point (a monochromatic light stimulation) of the straight line and the spectrum locus is determined as the dominant wavelength.

The fluorescent material having a composition represented by the formula (I) can be excited by light from the light emitting element having a peak emission wavelength in a range of 365 to 500 nm and emit light having a peak emission wavelength in a range of 620 to 670 nm. The light emitting device includes the fluorescent member that contains the fluorescent material having a composition represented by the formula (I) in a range of 115 to 150 parts mass to 100 parts mass of a resin, such that the light emitting device can emit red light having a dominant wavelength in a range of 610 to 630 nm with high luminous flux. The light emitting device can emit red light with high excitation purity. Excitation purity is the ratio of the distance WF/Ws (=Pe) of the distance WF between a chromaticity point W (white excitation point) on a straight line passing through the chromaticity point W (white excitation) of white light and the chromaticity point F of light emitted by the light emitting device and intersecting the spectrum locus at a monochromatic excitation S and the distance WS between the chromaticity point W (white excitation) and the chromaticity point S (monochromatic light excitation). Excitation purity Pe indicates how far a chromaticity of light emitted from the light emitting device is from a monochromatic stimulus. The higher the excitation purity, the closer light emitted from the light emitting device to a monochromatic stimulus.

The light emitting device preferably emit light of excitation purity Pe specified in JIS Z8701 and calculated on the chromaticity diagram, 99.0% or higher, preferably 99.3% or higher. With this arrangement, red light of high excitation purity and nearly monochromatic stimulus can be emitted from the light emitting device.

The content of the fluorescent material to 100 parts mass of resin in the phosphor member can be in a range of 115 to 150 parts mass, preferably 120 to 145 parts mass, more preferably in a range of 120 to 140 parts mass. When the content of the fluorescent material to 100 parts mass of resin in the fluorescent member is in a range of 115 to 150 parts mass, self-absorption of light may be likely caused, in which a portion of light emitted from the fluorescent material with wavelengths shorter than the peak emission wavelength is absorbed by the fluorescent material. When self-absorption of light in the fluorescent material occurs, luminous intensity of a portion of short wavelength side of the emission spectrum of the light emitting device decreases compared to luminous intensity of the emission spectrum of the light emitting device in which self-absorption does not occur, such that emission of light with wavelengths in a range of 365 to 500 nm decreases, which allows the light emitting device to emit red light of high luminous flux and high excitation purity. When the content of the fluorescent material to 100 parts mass of resin in the fluorescent member is less than 115 parts mass, the content amount of the fluorescent material may be insufficient and may result in a low excitation purity. Meanwhile, when the content of the fluorescent material to 100 parts mass of resin in the fluorescent member is greater than 150 parts mass, a low luminous flux may result. The light emitting device including the fluorescent member that contains the fluorescent material represented by the formula (I) in a range of 115 to 150 parts mass to 100 parts mass of resin can emit red light of high luminous flux and high excitation purity.

It is preferable that in the emission spectrum of the light emitting device, the peak emission wavelength λe_{P} is at a longer wavelength side than the peak emission wavelength λf_{P} of the emission spectrum of the fluorescent material contained in the fluorescent member, and a wavelength difference between the peak emission wavelength λe_{P} of the light emitting device and the peak emission wavelength λf_{P} of the fluorescent material: λe_{P}−λf_{P} (=Δλ_{P}) is 8 nm or greater. When the wavelength difference Δλ_{P} is 8 nm or greater, red light with high excitation purity can be emitted from the light emitting device. The light emitting device has the wavelength difference Δλ_{P} of 8 nm or greater, and can emit light having a dominant wavelength in a range of 610 to 630 nm. Even with high excitation purity, when the wavelength difference Δλ_{P} is 15 nm or less, the emission intensity of longer wavelength side that has low luminosity efficiency factor can be reduced, and light of high luminous flux can be emitted from the light emitting device. The wavelength difference Δλ_{P} is more preferably in a range of 8.2 to 15 nm, further preferably in a range of 8.5 to 12 nm. The wavelength difference Δλ_{P} may be in a range of 9 to 11 nm.

In an emission spectrum of light emitted from the light emitting device, the emission intensity at the peak emission wavelength of the light emitted from the light emitting element is preferably less than 0.2% with respect to the maximum luminous intensity. Hereinafter, a luminous intensity of light emitted from the light emitting element with respect to the maximum luminous intensity of the emission spectrum of light emitted from the light emitting device may be referred to as a “luminous intensity ratio Ir of the light emitting element”. When the luminous intensity ratio Ir is less than 0.2%, a portion of light emitted from the light emitting element that has a peak emission wavelength in a range of 365 to 500 nm can be prevented from leaking out of the light emitting device, allowing the light emitting device to emit light of high luminous flux and high excitation purity. The luminous intensity ratio Ir in the light emitted from the light emitting device can be more preferably not greater than 0.19%, further preferably not greater than 0.18%. The luminous intensity ratio Ir in the light emitted from the light emitting device may be not less than 0.02%, not less than 0.05%, or not less than 0.06%.

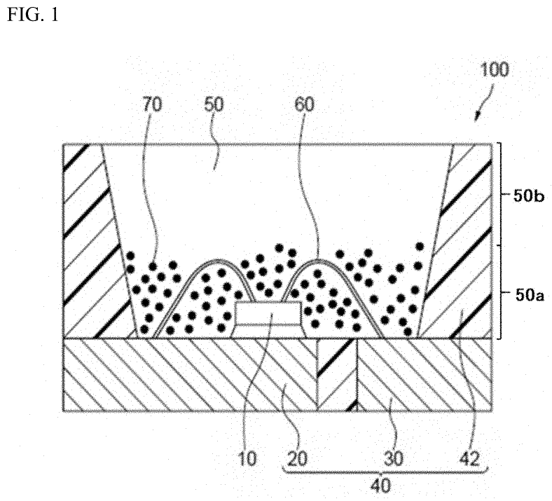

One example of the light emitting device will be described below with reference to the drawings. FIG. 1 is a schematic cross-sectional view of a light emitting device 100. The light emitting device 100 includes a light emitting element 10 that has a peak emission wavelength in a range of 365 to 500 nm to emit light of shorter wavelength side visible light (for example, in a range of 360 to 500 nm), and a molded body 40 as a support where the light emitting element 10 is disposed.

When the maximum luminous intensity in the emission spectrum of the light emitting device is set as 100% and the wavelength of light having emission intensity of 10% at shorter wavelength side than the peak emission wavelength of the light emitting device is set as λe_{S}, and when the maximum luminous intensity in the emission spectrum of the fluorescent material is set as 100% and the wavelength of light having emission intensity of 10% at shorter wavelength side than the peak emission wavelength of the fluorescent material is set as λf_{S}, the difference λe_{P}−λf_{P} (=Δλ_{P}) between the wavelength λe_{S} and the wavelength λf_{S} is preferably 8.5 nm or greater, more preferably 9 nm or greater, further preferably 10 nm or greater, and further more preferably 11 nm or greater. When the wavelength difference Δλ_{P} of 8.5 nm or greater is obtained by using a fluorescent material having the peak emission wavelength at a further shorter wavelength side with a relatively greater content in the fluorescent member, the peak emission wavelength of the emission spectrum of the light emitting device can be similar to the peak emission wavelength of red light with higher excitation purity. In order to obtain the light emitting device to emit red light of high excitation purity, the wavelength difference Δλ_{P} is preferably 15 nm or less.

When the maximum luminous intensity in the emission spectrum of the light emitting device is set as 100% and the wavelength of light having emission intensity of 10% at longer wavelength side than the peak emission wavelength of the light emitting device is set as λe_{L}, and when the maximum luminous intensity in the emission spectrum of the fluorescent material is set as 100% and the wavelength of light having emission intensity of 10% at longer wavelength side than the peak emission wavelength of the fluorescent material is set as λf_{L}, the difference λe_{L}−λf_{L} (=Δλ_{L}) between the wavelength λe_{L} and the wavelength λf_{L} is preferably 1.2 nm or less, more preferably 1.0 nm or less, further preferably 0.9 nm or less. When the wavelength difference Δλ_{L} of 1.2 nm or less is obtained by using a fluorescent material having the peak emission wavelength at a shorter wavelength side, a portion of emission spectrum at longer wavelength side that has a low luminosity efficiency factor can be reduced, such that a higher luminous flux can be obtained. Further, the peak emission in the emission spectrum of the light emitting device can be made similar to the peak emission in the emission spectrum of red light having high excitation purity, such that red light having high excitation purity can be emitted from the light emitting device. In order to emit red light having high excitation purity from the light emitting device, the difference between the wavelength λe_{L} and the wavelength λf_{L} is not required. That is, difference Δλ_{L} may be 0 nm.

The molded body 40 is formed by integrally molding a first lead 20 and a second lead 30 with a resin part 42. A recess defined by an upward-facing surface and one or more side surfaces is formed in the molded body 40 and the light emitting element 10 is mounted on the upward-facing surface. The light emitting element 10 has positive and negative electrodes and the positive and negative electrodes are respectively electrically connected to the first lead 20 and the second lead 30 through respective wires 60. The light emitting element 10 is covered by a phosphor member 50. The phosphor member 50 contains, for example, a fluorescent material 70 to convert the wavelength of light from the light emitting element 10, and a resin.

The fluorescent material 70 is distributed in the fluorescent member 50 with a greater amount closer to the light emitting element 10. The fluorescent member 50 includes a first layer 50a (hereinafter may be referred to as a “deposited layer”) containing a fluorescent material 70 and located near the light emitting element 10, and a second layer 50b (hereinafter may be referred to as a “resin layer”) substantially not containing a fluorescent material 70 and formed on the first layer 50a. Arranging the fluorescent material 70 close to the light emitting element 10 allows efficient wavelength conversion of light from the light emitting element 10. The relative arrangement between the fluorescent material 70 and the light emitting element 10 in the fluorescent member 50 is not limited to that in which the fluorescent material 70 and the light emitting element 10 are disposed closely. In view of effect of heat from the light emitting element 10 to the fluorescent material 70, the light emitting element 10 and the fluorescent material 70 can be arranged spaced apart from each other in the fluorescent member 50. Alternatively, the fluorescent material 70 may be distributed approximately uniformly in the whole portion of the fluorescent member 50 to obtain light in which color-unevenness can be further reduced. The thicknesses of the deposited layer and the resin layer directly above the light emitting element can be determined by observing a cross section of the light emitting device, in which a thickness of a portion showing the presence of the fluorescent material is determined as the thickness of the deposited layer and a thickness of a portion showing absence of the fluorescent material is determined as the thickness of the resin layer, and the sum of the thicknesses of the deposited layer and the resin layer is determined as the thickness of the fluorescent member.

In the light emitting device 100, the fluorescent material having a composition represented by the formula (I) is contained in the fluorescent member 50, such that the deposited layer that contains the fluorescent material 70 can be provided with a larger thickness at a portion directly above the light emitting element 10. Thus allowing for a larger thickness of the deposited layer that contains the fluorescent material 70, which can allow a greater luminous flux of the light emitting device 100. The thickness of the fluorescent member 50 directly above the light emitting element 10 is preferably 250 μm or less, more preferably 240 μm or less, further preferably 230 μm or less, and maybe 100 μm or greater or 150 μm or greater. When the thickness of the fluorescent member 50 is 250 μm or less, the thickness of the deposited layer (the first layer 50a) directly above the light emitting element 10 is preferably 200 μm or less, more preferably 190 μm or less, and maybe 30 μm or greater. At a portion directly above the light emitting element 10, a ratio Tr of the thickness of the deposited layer to the thickness of the fluorescent member 50: Tr=(thickness of the deposited layer (i.e., the first layer 50a))/(thickness of the fluorescent member 50) can be, for example, 95% or less, preferably 90% or less, and may be 30% or greater, preferably 50% or greater, more preferably 60% or greater, further preferably 70% or greater, further more preferably 80% or greater.

At a portion directly above the light emitting element 10, a ratio of the thickness of the resin layer (the second layer 50b) to the thickness of the fluorescent member 50: (thickness of the resin layer (i.e., the second layer 50b))/(thickness of the fluorescent member 50) may be 70% or less and may be 5% or greater. That is, in the fluorescent member 50, the resin layer may have a thickness smaller than that of the deposited layer containing the fluorescent material 70.

### Light Emitting Element

The light emitting element 10 preferably has a peak emission wavelength in a range of 365 to 500 nm, preferably in a range of 400 to 460 nm.

The light emitting element 10 is preferably a semiconductor light emitting element that includes, for example, a nitride-based semiconductor (In_{X}Al_{Y}Ga_{1-X-Y}N, in which X and Y respectively satisfy 0≤X, 0≤Y, and X+Y≤1). With the use of a semiconductor light emitting element as an excitation light source, a light emitting device having a high linearity of outputting to inputting in high efficiency and having high stability to mechanical impacts can be obtained. In order to efficiently excite the fluorescent material, the light emitting element 10 preferably has a half width of the emission spectrum of 30 nm or less. In the present specification, the term “half width of the emission peak” refers to a full width at half maximum (FWHM) of an emission spectrum curve. That is, a width of an emission spectrum curve between points which are 50% of the maximum emission peak intensity.

### Fluorescent Member

The fluorescent member includes the fluorescent material 70 and a resin. The fluorescent member 50 may contain a light diffusing material in addition to the fluorescent material 70 and the resin. The fluorescent material 70 preferably contain alkaline-earth metal elements including Ca and Sr and a nitride fluorescent material containing Si, Al, and Eu in its composition. It is preferable that the fluorescent material 70 contains a fluorescent material to be excited by light having a peak emission wavelength in a range of 365 to 500 nm emitted from the light emitting element, and emit fluorescent light having a peak emission wavelength in a range of 620 to 670 nm, the fluorescent material has a composition represented by a formula (I) shown below, and that the fluorescent material is a nitride fluorescent material. The fluorescent material 50 may also contain a fluorescent material having a composition that is different from the composition represented by the formula (I) shown below.

The fluorescent material 70 preferably includes a fluorescent material having a composition represented by formula (I) shown below.

CaₛSrₜEuᵤSiᵥAl_{w}Nₓ (I)

In which, s, t, u, v, w, and x respectively satisfy 0.005≤s≤0.995, 0≤t≤0.95, 0.005≤u≤0.04, 0.8≤s+t+u≤1.1, 0.8≤v≤1.2, 0.8≤w≤1.2, 1.8≤v+w≤2.2, and 2.5≤x≤3.2.

In the composition represented by the formula (I), when the variable w indicating a molar ratio of Al to 1 mole of the composition is 1 (w=1), the variables s, t, u, and v in the formula (I) can be expressed in ranges shown below.

In the composition represented by the formula (I), the variable s representing a molar ratio of Ca is preferably in a range of 0.1 to 0.3 (0.1≤s≤0.3), more preferably in a range of 0.15 to 0.25 (0.15≤s≤0.25). In the composition represented by the formula (I), the variable t representing a molar ratio of Sr is preferably in a range of 0.7 to 0.95 (0.7≤t≤0.95), more preferably in a range of 0.75 to 0.9 (0.75≤t≤0.9). In the composition represented by the formula (I), the molar ratio of Sr is preferably greater than the molar ratio of Ca relative to 1 mole of the composition. The fluorescent material having a composition represented by the formula (I), in which the molar ratio of Sr is greater than the molar ration of Ca, can efficiently absorb light from the light emitting element having a peak emission wavelength in a range of 365 to 500 nm and for example emits fluorescent light in a range of 610 to 700 nm with a peak emission wavelength in a range of 620 to 670 nm. Further, self absorption of light by the fluorescent material, in which, a portion of fluorescent light emitted by the fluorescent material is absorbed by the fluorescent material, occurs even with a large content of the fluorescent material in the fluorescent member used in the light emitting device, such that light having a dominant wavelength in a range of 610 to 630 nm is emitted from the light emitting device. In the composition represented by the formula (I), the variable u representing a molar ratio of Eu that is an activator of the fluorescent material is preferably in a range of 0.01 to 0.03 (0.01≤u≤0.03), more preferably in a range of 0.01 to 0.025 (0.01≤u≤0.025). When the variable u representing the molar ratio of Eu that is an activator of the fluorescent material is in the range of 0.01 to 0.03 in the composition represented by the formula (I), the fluorescent material can efficiently absorb light from the light emitting element having a peak emission wavelength in a range of 365 nm to 500 nm and emit light having a second peak emission wavelength in a range of 620 nm to 670 nm. In the composition represented by the formula (I), a total molar ratio (s+t+u) of the variables s, t, and u is preferably in a range of 0.85 to 1.0 (0.85≤s+t+u≤1.0), more preferably in a range of 0.87 to 0.95 (0.87≤s+t+u≤0.95). In the composition represented by the formula (I), the variable v representing a molar ratio of Si is preferably in a range of 1.0 to 1.1 (1.0≤v≤1.1), more preferably in a range of 1.01 to 1.07 (1.01≤v≤1.07).

The fluorescent material having a composition represented by the formula (I) may contain at least one element selected from the group consisting of Ba, Mg, Ge, B, Ce, Mn, and Tb with an amount so as not to affect the luminous characteristics, particularly the luminous intensity and color of light, as element(s) other than the compositional elements contained in the formula (I).

The fluorescent material having a composition represented by the formula (I) may contain fluorine element. Fluorine element may be contained in the composition, for example, in the course of manufacturing the fluorescent material. When fluorine element is included in a fluorescent material, for example, in the fluorescent material having a composition represented by the formula (I), the content of fluorine element to 100 mol % of Al in 1 mole of the composition may be 6 mol % or less, may be in a range of 1×10⁻³ to 6 mol %, in a range of 3×10⁻³ to 4 mol %, or in a range of 5×10⁻³ to 1.5 mol %. When fluorine element is contained in the fluorescent material in a range described above, the luminous efficiency of the fluorescent material tends to increase.

The fluorescent material having a composition represented by the formula (I) may include oxygen element. The oxygen element may be contained in the composition of the fluorescent material, or may be contained in the fluorescent material as an impurity, an oxide of an element that is a composition of the fluorescent material. Examples of the oxide contained as an impurity in the fluorescent material include an oxide containing an alkaline-earth element, an oxide containing aluminum, an oxide containing silicon, and an oxynitride. When oxygen element is included in the fluorescent material represented by the formula (I), the content of oxygen element to 100 mol % of Al in 1 mole of the composition may be in a range of 5 to 50 mol %, in a range of 6 to 40 mol %, in a range of 7 to 30 mol %, in a range of 7 to 15 mol %, or in a range of 7 to 12 mol %. Even when oxygen element is included as an impurity in the fluorescent material represented by the formula (I), when the percentage content of the oxygen element is in a range described above, the luminous efficiency of the fluorescent material tends to be improved.

The molar ratios of the elements contained in the fluorescent material can be measured by an appropriate routine procedure, such as X-ray fluorescence (XRF) analysis, an ion chromatography (IC), or an inductively coupled prasma-atomic emission spectroscopy (ICP-AES).

The fluorescent material having a composition represented by the formula (I) can be excited by light from the light emitting element having a peak emission wavelength in a range of 365 to 500 nm and emit light in a wavelength range of 610 to 700 nm, with a peak emission wavelength in a range of 620 to 670 nm, or a range of 625 to 650 nm.

The fluorescent material having a composition represented by the formula (I) has a reflectance at a wavelength 450 nm preferably 20% or less, more preferably 15% or less, further preferably 10% or less. When the fluorescent material having a composition represented by the formula (I) has a reflectance at a wavelength 450 nm 20% or less, efficient absorption of light having a peak emission wavelength in a range of 365 to 500 nm can be obtained. The fluorescent material having a composition represented by the formula (I) may have a reflectance 2% or greater at a wavelength of 450 nm. The reflectance of the fluorescent material can be measured by using a spectrophotometer on a solid sample of the fluorescent material. For the reference of the reflectance, calcium monohydrogen phosphate (CaHPO₄) may be used. The reflectance of the fluorescent material can be determined as a relative reflectance to calcium monohydrogen phosphate as a reference sample.

The fluorescent material having a composition represented by the formula (I) has a low reflectance of 20% or less at 450 nm, which may lead to an increase of the content of the fluorescent material in the fluorescent member, which causes self-absorption within the fluorescent member; a phenomenon in which fluorescent light emitted from a fluorescent material is absorbed by a different fluorescent material within the fluorescent member. The self-absorption within the fluorescent member lead by an increase of the content of the fluorescent material in the fluorescent member employed in the light emitting device leads to a decrease in the luminous intensity of a portion of light-emission spectrum at a shorter wavelength side with respect to the peak emission wavelength of the light emitting device. The fluorescent material having a composition represented by the formula (I) is excited by light from the light emitting element and emits light, for example, in a wavelength range of 610 to 700 nm, with a peak emission wavelength in a range of 620 to 670 nm that is similar to the peak wavelength of the luminosity curve. The light emitting device employing the fluorescent member containing the fluorescent material having a peak emission wavelength at shorter wavelength side and similar to the peak wavelength of the luminosity curve has a smaller luminous intensity at longer wavelength side that has a low luminosity efficiency factor and a smaller luminous intensity. Accordingly, the light emitting device having a dominant wavelength in a range of 610 to 630 nm can emit red light with high excitation purity and also with high luminous flux. Luminous flux is the measure of the perceived power of light by the human eye. Light having an emission spectrum deviated from the luminosity curve tends to have a low luminous flux. For example, the photopic relative luminosity curve has a peak wavelength at 555 nm and the scotopic relative luminosity curve has a peak wavelength at 507 nm. A light emitting device configured to emit light having a dominant wavelength in a range of 610 to 630 nm emits red light, in which, an increase in the excitation purity results in a deviation of the peak emission wavelength in the emission spectrum of the light emitting device from the luminosity curve, such that the luminous flux tends to decrease. The light emitting device is configured to emit light having a peak emission wavelength, for example, in a range of 620 to 670 nm, among the wavelength range of 610 to 700 nm of red light. The fluorescent member in the light emitting device includes a high content of the fluorescent material in a range of 115 to 150 parts mass, and the reflectance of the light emitting device at 450 nm is a low value of 20% or less. Accordingly, even when the light emitting device is configured to emit light having a dominant wavelength in a range of 610 to 630 nm in the emission spectrum deviated from the luminosity curve, red light with high excitation purity and high luminous flux can be emitted.

The fluorescent material having a composition represented by the formula (I) has a volume average particle size preferably in a range of 5 to 50 μm, more preferably 10 μm or greater, further preferably 15 μm or greater, more preferably 40 μm or less, further preferably 30 μm, further more preferably 25 μm or less. When the fluorescent material having a composition represented by the formula (I) has a volume average particle size greater than 5 μm, a high emission intensity of fluorescent light emitted from the fluorescent material can be obtained, while with the volume average particle size 50 μm or less, working efficiency in the manufacturing the light emitting device can be improved. The volume average particle size of the fluorescent material can be measured by using a laser diffraction-type particle-size distribution measuring device (for example, MASTER SIZER 3000, manufactured by Malvern Instruments Ltd). The volume average particle size of the fluorescent material can be represented by an average particle diameter (Dm: median diameter) at a cumulative value of 50% in a particle distribution.

The fluorescent material 70 contained in the fluorescent member 50 may have a specific gravity of 3.3 g/cm³ or greater, 3.6 g/cm³ or greater, or 3.7 g/cm³ or greater. The fluorescent material contained in the fluorescent member may have a specific gravity of 4.3 g/cm³ or less, 4.1 g/cm³ or less or 3.9 g/cm³ or less. When the specific gravity of the fluorescent material is 3.3 g/cm³, efficiency in precipitating the fluorescent material 70 in the fluorescent member 50 can be improved such that the deposited layer containing the fluorescent material 70 can be formed with higher density. With this arrangement, scattering loss the dust to contains the fluorescent material 70, which Deposited Layer can be reduced.

The fluorescent material 50 may also contain a fluorescent material having a composition that is different from the composition represented by the formula (I). Examples of such a fluorescent material include (Sr, Ca)LiAl₃N₄:Eu, (Ca, Sr, Ba)₂Si₅N₈:Eu, (Ca, Sr, Ba)S:Eu, K₂(Si, Ti, Ge)F₆:Mn, and 3.5MgO.0.5MgF₂.GeO₂:Mn.

The fluorescent member 50 can contain for example, at least one resin selected from epoxy resins and silicone resins, in addition to the fluorescent material 70.

When needed, the phosphor member may include one or more components in addition to the fluorescent material 70 and the resin. Examples of such additional components include a filler material such as silicon oxide, barium titanate, titanium oxide, aluminum oxide; an optical stabilizer; and a coloring agent. When the fluorescent member 50 includes, for example, a filler material as an additional component, the content of the filler material can be in a range of 0.01 to 20 mass % to 100 mass % of the resin.

### Method of Manufacturing Fluorescent Material

The fluorescent material having a composition represented by the formula (I) can be manufactured, for example, by using a method including heat treating a raw material mixture containing an Eu source, an alkaline-earth metal source that contains Ca and Sr, an Al source, and a Si source. It is preferable that the mixed raw material may further contains an alkaline earth metal fluoride. With the use of a mixed raw material containing an alkaline earth metal fluoride, a fluorescent material of higher luminous efficiency can be manufactured.

For the Eu source, the alkaline-earth metal source, the Al source, and the Si source, one or more compounds respectively containing one or more elements such as Eu, the alkaline-earth metals, and Al or Si; single metals of those elements, an alloy containing those elements may be used. Examples of compounds containing Eu, the alkaline-earth metal element, and Al or Si include an oxide, a hydroxide, a nitride, an oxynitride, a fluoride, and a chloride, each containing the elements shown above. In order to obtain the fluorescent material having a composition represented by the formula (I), a compound containing Eu, the alkaline-earth metal element, and Al or Si is preferably a nitride or an oxynitride. More specific examples include EuN, Ca₃N₂, a mixture of Sr₂N and SrN, AlN, and Si₃N₄. Eu, the alkaline-earth metal element, and Al or Si may be provided in respective compounds or may be provided in one or more compound containing one or more of those elements.

The raw material mixture may include a flux material of fluoride containing the alkaline-earth metal element. When the raw material mixture contains a fluoride that contains the alkaline-earth metal element, the content of the fluoride as elemental fluorine to 100 mol % content of elemental Al contained in the raw material mixture is preferably in a range of 2 to 25 mol %, more preferably in a range of 3 to 18 mole %, further preferably in a range of 4 to 13 mol %. When the content of the fluoride is 2 mol % or greater, sufficient effect of flux can be obtained. Effect of the flux is saturated at a certain amount such that with the content of the fluoride 25 mol % or less, the effect of the flux can be expected without containing an excess amount of the flux.

The raw material mixture may be obtained by measuring compounds containing the constituting elements to obtain an intended compounding ratio, then mixing the raw materials by using a mixing machine such as a ball mill, a henschel mixer, or a V-blender. The mixing can be performed as dry-mixing or as wet mixing with a solvent.

The fluorescent material having a composition represented by the formula (I) can be obtained by heat treating the raw material mixture. The heat treatment temperature of the raw material mixture can be 1200° C. or greater, preferably 1500° C. or greater, more preferably 1900° C. or greater. The heat treatment temperature of the raw material mixture can be 2200° C. or less, preferably 2100° C. or less, more preferably 2050° C. or less. Heat treatment at a temperature of 1200° C. or greater can facilitate entering of Eu in the crystal grain(s), such that the fluorescent material of desired component can be efficiently formed. Also when the heat treatment temperature is 2200° C. or less, decomposition of the fluorescent material that has been formed tends to decrease. Heat treatment of the raw material mixture can be performed at a constant temperature or by multi-stage heating in which a plurality of different temperatures are applied in the heat treatment.

The heat treatment is preferably performed in an atmosphere containing nitrogen gas, more preferably in a substantially nitrogen gas atmosphere. In such an atmosphere containing nitrogen gas, silicon that may be contained in the raw material mixture can also be nitrided. Moreover, decomposition of a nitride raw material and/or the produced fluorescent material can be reduced or prevented.

In the heat treatment of the raw material mixture, a holding time at a predetermined temperature may be provided. For example, the holding time can be in a range of 0.5 to 48 hours, preferably in a range of 1 to 30 hours, more preferably in a range of 2 to 20 hours. The holding time of 0.5 hours or greater can facilitate more uniform growth of the particles. The holding time of 48 hours or less can further reduce the decomposition of the fluorescent material.

The heat treatment of the raw material mixture can be performed using, for example, a gas-pressure electric furnace. The raw material mixture can be placed in a crucible, a boat, or the like, made of carbon material such as graphite, boron nitride (BN), or the like, and subjected to the heat treatment.

The fluorescent material obtained by the heat treatment may be subjected to a step of sizing, in which a combination of processing techniques such as crushing, pulverizing, classifying, etc., may be performed. Through the step of sizing, a powder having a predetermined particle size can be obtained. More specifically, the fluorescent material is roughly crushed, then, using a general crushing device such as a ball mill, a jet mill, or a vibration mill, further crushed into a predetermined particle size. However, if the pulverization is excessively performed, defects may occur on the surfaces of the fluorescent material particles, which may result in a decrease in the emission intensity. When the fluorescent material particles of unintended particle size due to the pulverization are mixedly present, classification may be performed to adjust the range of the particle size.

### Method of Manufacturing Light Emitting Device

A method of manufacturing a light emitting device according to a third embodiment of the present invention includes steps of disposing a light emitting element on a support, the light emitting element having a peak emission wavelength in a range of 365 to 500 nm, providing a fluorescent material and a resin, the fluorescent material having a composition represented by a formula (I) and configured to be excited by light from the light emitting element to emit light having a peak emission wavelength in a range of 620 to 670 nm, mixing the fluorescent material and the resin to obtain a mixture in which a content of the fluorescent material is in a range of 115 to 150 parts relative to 100 parts mass of the resin to obtain a composition for fluorescent member, disposing the composition for fluorescent member on the light emitting element to obtain a fluorescent member, to obtain a light emitting device to emit light having a dominant wavelength in a range of 610 to 630 nm. The light emitting device obtained through the method described above is the light emitting device according to the first embodiment, in which a fluorescent material similar to the fluorescent material having a composition represented by the formula (I) used in the light emitting device according to the first embodiment can also be used.

In the method of manufacturing a light emitting device, an experimental light emitting device may be produced by disposing a light emitting element on a support, the light emitting element having a peak emission wavelength in a range of 365 to 500 nm, providing a fluorescent material and a resin, the fluorescent material having a composition represented by a formula (I) and configured to be excited by light from the light emitting element to emit light having a peak emission wavelength in a range of 620 to 670 nm, mixing the fluorescent material and the resin to obtain a mixture, disposing the mixture on the light emitting element to form a fluorescent member. A peak emission wavelength λe_{P} of the emission spectrum of the experimental light emitting device is measured and compared to a peak emission wavelength λf_{P}, of the emission spectrum of the fluorescent material represented by the formula (I), and the amount of the fluorescent material is adjusted such that a difference of the peak emission wavelengths λe_{P}−λf_{P} is 8 nm or greater in the light emitting device.

Next, the method of manufacturing a light emitting device will be described with reference to FIG. 1 showing one embodiment of the light emitting device.

The light emitting element is preferably disposed on a molded body 40 that is a support formed by integrally molding a first lead 20 and a second lead 30 with a resin part 42.

The fluorescent member 50 is formed using a composition for fluorescent member that is preferably a mixture of the resin and the fluorescent material having a composition represented by the formula (I). In the mixture, relative to 100 parts mass of the resin, the content of the fluorescent material represented by the formula (I) can be in a range of 115 to 150 parts mass, preferably in a range of 120 to 145 parts mass, further preferably in a range of 120 to 140 parts mass.

The fluorescent member 50 can be formed by, for example, disposing a mixture containing the fluorescent material 70 and the resin in a recess defined in the molded body 40 to cover the light emitting element 10. The mixture can be disposed in the recess of the molded body 40 by using any appropriate technique which allows controlling of the amount of the mixture disposed in the recess, examples of such technique include potting and jet dispersing. Generally, the fluorescent material 70 and the resin have different specific gravities, such that gravitationally guiding the fluorescent material 70 to an upward-facing surface of the recess (along a direction toward a lower surface of the molded body 40), the fluorescent material 70 can be settled toward the upward-facing surface having the light emitting element 10 disposed thereon, such that a deposited layer (a first layer 50a) containing the fluorescent material 70 and the resin layer (a second layer 50b) can be formed in the fluorescent member 50. Alternatively, an acceleration such as centrifugal force may be applied in a direction perpendicular to the lower surface such that the fluorescent material 70 can be deposited in the upward-facing side in the recess. The use of centrifugal force is particularly efficient when a large ratio of the fluorescent material relative to the resin is used. The resin contained in the fluorescent member 50 may be a thermosetting resin, which can be cured by applying heat after the fluorescent material 70 is settled, such that the fluorescent member 50 in which the fluorescent material 70 is unevenly distributed can be obtained.

### Examples

Next, the present disclosure will be more specifically described with reference to examples, which however are not intended to limit the present disclosure.

### Manufacturing Fluorescent Material

Before manufacturing the light emitting device, fluorescent materials 1 to 3 shown in Tables 1 and 2, configured to emit red light are produced and evaluated using the evaluation method shown below. The results are shown in Table 1.

### Luminous Characteristics

Luminous characteristics of the fluorescent materials 1 to 3 obtained using the method to be described later below were measured as described below. Emission spectra were measured using a quantum effect measuring device (manufactured by QE-2000, OTSUKA ELECTRONICS CO., LTD).

Excitation light of a wavelength 450 nm was irradiated on each of the fluorescent materials and emission spectra at room temperature (25±5° C.) were measured. The wavelength at the maximum emission intensity in the emission spectrum of each of the fluorescent materials was determined as the peak emission wavelength λf_{P} (nm). Also, the full width at half maximum (FWHM) of the peak emission of the emission spectrum of each of the fluorescent materials was determined. In the specification, the term “half band width (full width at half maximum) refers to the width of wavelength, a line shape at 50% intensity of the maximum value of emission intensity in the emission spectrum. Also, emission intensity at the peak emission in the emission spectrum of each of the fluorescent materials was determined, and using the emission intensity of each of the fluorescent materials set to 100%, the relative emission intensities of the fluorescent materials 2 and 3 were determined.

### Reflectance

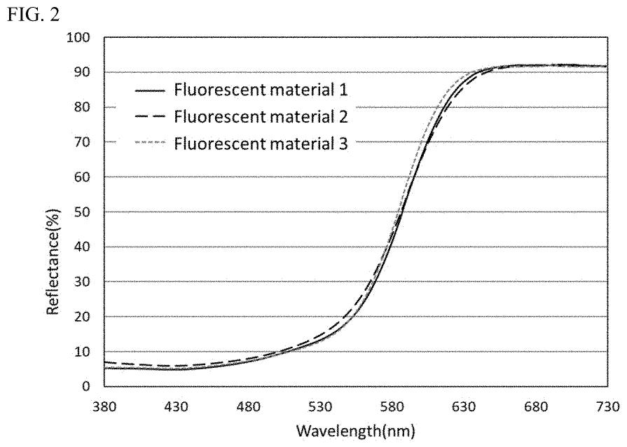

Reflectance and reflection spectrum of the fluorescent materials 1 to 3 were measured using a spectrofluorometer (F-4500, manufactured by Hitachi High-Technologies Corporation). At room temperature (18 to 28° C.), light from an excitation light source (xenon lamp) was irradiated on each of the fluorescent materials serving as a specimen, and a reflection spectrum in a wavelength range of 380 to 730 nm was measured. Using calcium monohydrogen phosphate (CaHPO₄) as a standard specimen, the reflectance of calcium monohydrogen at a wavelength 450 nm was set as a standard, the reflectance of each of the fluorescent materials 1 to 3 at 450 nm was determined as relative reflectance (%). The reflection spectra of the fluorescent materials 1 to 3 in a wavelength range 380 to 730 nm are shown in FIG. 2.

### Volume Average Particle Size

Using a laser diffraction-type particle size distribution analyzer (MASTER SIZER 3000, manufactured by Malvern Instruments Ltd.), a volume average particle size (Dm: median diameter), a size of particle taken at 50% of the volume-cumulative frequency of each of the fluorescent materials 1 to 3 was measured.

### Specific Gravity

The specific gravity (g/cm³) of each of the fluorescent materials 1 to 3 was calculated from the volume (cm³) and weight (g) of each of the fluorescent materials.

### Composition Analysis

Composition of each of the fluorescent materials 1 to 3 was analyzed appopriately selecting an ICP-AES spectrometer (manufactured by Prtkin Elmer Inc.), an ionchromatography system (manufactured by Nippon Dionex K.K./Thermo Fisher Scientific K.K.), and an oxygen/nitrogen analyzed (HORIBA, Ltd.). With the molar ratio of Al set to 1, the molar ratio of each element in the compositions of the fluorescent materials are shown in Table 2.

### Fluorescent Material 1

In the composition represented by the formula (I): CaₛSrₜEuᵤSiᵥAl_{w}Nₓ (I), design values were set to s=0.19, t=0.81, u=0.02, v=1, and w=1. Ca₃N₂, CaF₂ (0.03 mol % with respect to the total Ca source s), SrNₙ (a mixture of Sr₂N and SrN in which n=⅔), AlN, Si₃N₄, and EuN were used as the raw materials. The raw materials were measured to satisfy the designed values and mixed in a glove box under nitrogen atmosphere and the raw material mixture was obtained. In the composition, based on the design values of positive ions, x was set to satisfy x=3, and an effect of oxygen contained in the raw material mixture was considered as negligible. The raw material mixture was put in a crucible and a heat treatment was performed under N₂ gas atmosphere, with a gas pressure of 0.92 Mpa (gauge pressure), at a temperature 2,040° C. for 30 minutes. The obtained fluorescent material was indicated as a fluorescent material 1. The molar ratio of each compositional element of the fluorescent material 1 was confirmed to be the value shown in Table 2.

### Fluorescent Material 2

In the composition represented by the formula (I):

CaₛSrₜEuᵤSiᵥAl_{w}Nₓ (I),

design values were set to s=0.13, t=0.87, u=0.02, v=1, and w=1. That is, the molar ratio of Sr was set to greater than that of the fluorescent material 1 such that the peak emission wavelength of the fluorescent material 2 is located at a shorter wavelength side with respect to the peak emission wavelength of the fluorescent material 1. Otherwise is set similar to that in the fluorescent material 1, a row material mixture was obtained. The raw material mixture was heat treated similar to that as in the fluorescent material 1, and the fluorescent material 2 was obtained. The molar ratio of each compositional element of the fluorescent material 2 was confirmed to be the value shown in Table 2.

### Fluorescent Material 3

In the composition represented by the formula (I):

CaₛSrₜEuᵤSiᵥAl_{w}Nₓ (I),

design values were set to s=0.06, t=0.90, u=0.02,v=1, and w=1. That is, the molar ratio of Sr was set to greater than that of the fluorescent material 2 such that the peak emission wavelength of the fluorescent material 3 is located at a shorter wavelength side with respect to the peak emission wavelength of the fluorescent material 1 or 2. Otherwise is set similar to that in the fluorescent material 1, a row material mixture was obtained. The raw material mixture was heat treated similar to that as in the fluorescent material 1, and the fluorescent material 3 was obtained. The molar ratio of each compositional element of the fluorescent material 3 was confirmed to be the value shown in Table 2.

TABLE 1

| | | Relative | | | | |
|---|---|---|---|---|---|---|
| | Volume average | luminous | Peak emission | | Reflectance at | |
| | particle size Dm | intensity Ie_{P} | wavelength λe_{P} | Half bandwidth | 450 nm | Specific gravity |
| | (μm) | (%) | (nm) | (nm) | (%) | (g/cm³⁾ |
| Fluorescent | 20.0 | 100.0 | 639 | 639 | 6.1 | 3.72 |
| material 1 | | | | | | |
| Fluorescent | 19.8 | 107.6 | 631 | 631 | 5.4 | 3.87 |
| material 2 | | | | | | |
| Fluorescent | 25.8 | 110.9 | 623 | 623 | 5.6 | 4.02 |
| material 3 | | | | | | |

In the emission spectra of the fluorescent materials 1 to 3, the peak emission wavelengths of the fluorescent materials 3, 2, and 1 were located in this order from shorter wavelength side. All the fluorescent materials 1 to 3 exhibited 20% or smaller reflectance at 450 nm. Compared to the fluorescent material 1, the fluorescent material 2 had a similar volume average particle size Dm but exhibited a smaller reflectance at 450 nm and emitted fluorescent light having an emission spectrum with a smaller half band width and greater emission component at shorter wavelength side. Compared to the fluorescent material 1, the fluorescent material 3 had a volume average particle size Dm greater than that of fluorescent materials 1 and 2, exhibited a smaller reflectance at 450 nm than that of the fluorescent material 1, and emitted fluorescent light having an emission spectrum with a half band width smaller than that of the fluorescent materials 1 and 2, and greater emission component at shorter wavelength side.

TABLE 2

| | Composition of fluorescent material (molar ratio) | | | | | | | | |
|---|---|---|---|---|---|---|---|---|---|
| | Ca | Sr | Eu | Si | Al | N | O | Sr + Ca + Eu | F |
| Variable | s | t | u | v | w | x | — | s + t + u | — |
| Fluorescent | 0.20 | 0.73 | 0.02 | 1.05 | 1 | 2.91 | 0.09 | 0.96 | 0.002 |
| material 1 | | | | | | | | | |
| Fluorescent | 0.14 | 0.80 | 0.02 | 1.04 | 1 | 2.91 | 0.10 | 0.96 | 0.001 |
| material 2 | | | | | | | | | |
| Fluorescent | 0.06 | 0.90 | 0.02 | 1.05 | 1 | 2.96 | 0.13 | 0.98 | 0.002 |
| material 3 | | | | | | | | | |

The fluorescent materials 1 to 3 had respective compositions approximately corresponding to designed values. Oxygen and Fluorine were contained in the fluorescent materials 1 to 3 having compositions represented by the formula (I).

### Example 1 and Comparative Example 1

### Manufacturing Light Emitting Device

Using a semiconductor light emitting element using a nitride-based semiconductor and having a peak emission wavelength at 454 nm (hereinafter may be referred to as “blue light emitting LED”), respective light emitting devices of Examples and Comparative Examples were manufactured as described below.

More specifically, as shown in FIG. 1, the light emitting element 10 that is a blue light emitting LED was disposed on the upward-facing surface of the recess defined in the molded body 40 that is a support and formed by integrally molding a first lead 20 and a second lead 30 with a resin part 42.

In order to obtain light emitted from the light emitting device 100 with a dominant wavelength of about 615 nm, the fluorescent material 1 or 2 was added to a silicone resin such that the content of the fluorescent material to 100 parts mass of the silicone resin satisfies the content shown in Table 3, and mixed with the silicone resin and dispersed in the silicone resin, then further, defoaming was performed. Thus, the composition for fluorescent member was provided.

The composition for fluorescent member was disposed by potting on the light emitting element 10 disposed in the recess of the molded body 40.

Then, heat was applied to harden the composition for fluorescent member to form the fluorescent member 50, and the light emitting device 100 was manufactured.

### Example 2 and Comparative Example 2

In order to obtain light emitted from the light emitting device 100 with a dominant wavelength of about 612 nm, the composition for fluorescent member was provided, in which the fluorescent material 2 or 3 was added to a silicone resin such that the content of the fluorescent material to 100 parts mass of the silicone resin satisfies the content shown in Table 3, and mixed with the silicone resin and dispersed in the silicone resin, then further, defoaming was performed. Thus, the composition for fluorescent member was provided. The light emitting device 100 was manufactured in similar manner as in Example 1 except for forming the fluorescent member 50 using the composition for fluorescent member.

### Evaluation 1 of Light Emitting Device

The light emitting devices of Examples and Comparative Examples were evaluated by the method shown below. The results are shown in Table 3.

### Luminous Characteristics

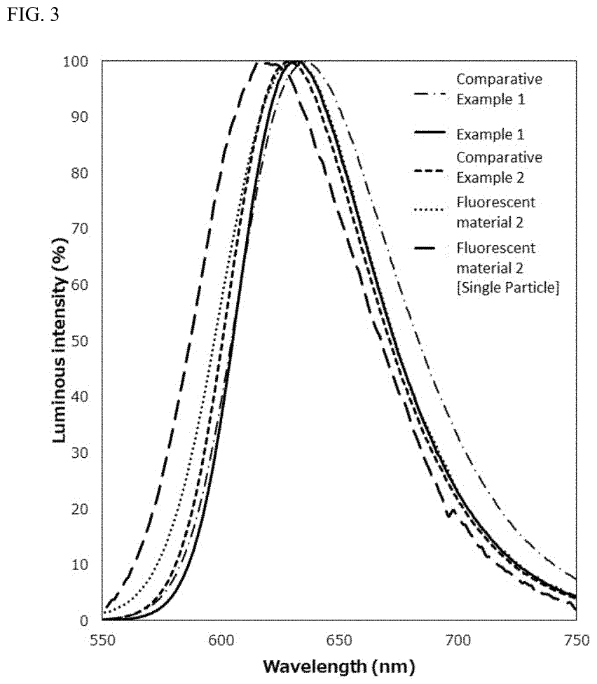

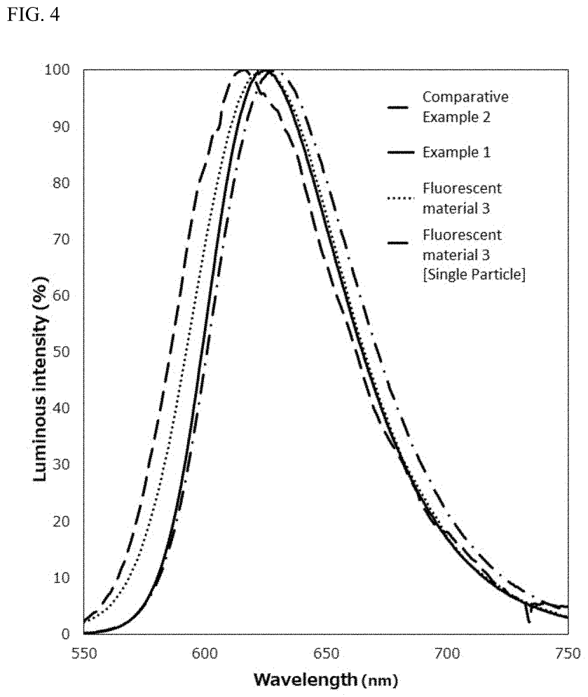

Luminous characteristics of the light emitting devices of Examples and Comparative Examples were measured as shown below. Emission Spectrum of each of the light emitting device was measured using a spectrophotometric analyzer (PMA-11, manufactured by Hamamatsu Photonics K.K.) with an integrating sphere. FIG. 3 and FIG. 4 respectively show emission spectra of the light emitting devices, an emission spectrum of a corresponding fluorescent material filled in a cell and measured, and an emission spectrum of a single particle obtained from the powder of the fluorescent material. In measuring the emission spectrum of each of the fluorescent materials, the fluorescent material is filled in a cell, an excitation light having an wavelength of 450 nm was irradiated on the fluorescent material filled in the cell, and the emission spectrum was measured using a quantum effect measuring device (QE-2000, manufactured by Otsuka Electronics Co., Ltd.) at room temperature (25±5° C.). In measuring the emission spectrum of a single particle of each of the fluorescent materials, an excitation light having an wavelength of 450 nm was irradiated on a single particle of the fluorescent material, and the emission spectrum was measured using a quantum effect measuring device (QE-2100, manufactured by Otsuka Electronics Co., Ltd.) at room temperature ((25±5° C.). In FIG. 3, the emission spectrum of each of the light emitting devices are shown as a relative emission spectrum in which the maximum emission intensity is set to 100%. In FIG. 3, the emission spectra of the fluorescent material 2 and a single particle of the fluorescent material 2 are shown as relative emission spectra in which the maximum emission intensities are respectively set to 100%. FIG. 4 shows emission spectra of the light emitting devices of Example 2 and Comparative Example 2, an emission spectrum of the fluorescent material 3, and an emission spectrum of a single particle of the fluorescent material 3. In FIG. 4, the emission spectrum of each of the light emitting devices of Example 2 and Comparative Example 2 are shown as relative emission spectra in which the maximum emission intensities are respectively set to 100%. In FIG. 4, the emission spectra of the fluorescent material 3 and a single particle of the fluorescent material 3 are shown as relative emission spectra in which the maximum emission intensities are respectively set to I00%.

### Chromaticity Coordinates (x, y)

Chromaticity Coordinates (x, y) on CIE1931 chromaticity diagram of light emitted from each of the light emitting devices of Examples and Comparative Examples were determined using an optical measurement system employing a combination of a multichannel spectroscope and an integrating sphere. More specifically, chromaticity coordinates (x, y) of ten light emitting devices of each of Examples and Comparative Examples were measured and the arithmetic average values were respectively set as the chromaticity coordinates (x, y) of the light emitting devices the Examples and Comparative Examples.

### Dominant Wavelength

The dominant wavelength is determined such that on JIS Z8701 chromaticity diagram, assuming a strain line passing through chromaticity coordinates (x=0.33333, y=0.33333) of white light and chromaticity coordinates (x, y) of light emitted from each of the light emitting device, the wavelength of an intersection point of the straight line and the spectrum locus is determined as the dominant wavelength. More specifically, dominant wavelengths of ten light emitting devices of each of Examples and Comparative Examples were measured and the arithmetic average value was set as the dominant wavelength of the light emitting device of each of the Examples and Comparative Examples.

### Excitation Purity Pe (%)

Excitation Purity Pe (%) of each of the light emitting devices of Example 1 and Comparative Example 1 each having the dominant wavelength set to 615 nm was determined such that on JIS Z8701 chromaticity diagram, assuming a strain line passing through chromaticity point W (x_{w}=0.33333, y_{w}=0.33333) of white light and monochromatic stimulus S₁(xₛ₁=0.68008, yₛ₁=0.31975), a distance between the chromaticity point W and the chromaticity point F (chromaticity coordinates (x, y) of each light emitting device) and a distance between the chromaticity point Wand the monochromatic stimulus S₁ were measured, and a ratio WF/WS₁ was determined as excitation purity (%). More specifically, excitation purity Pe (%) often light emitting devices of each of Example 1 and Comparative Example 1 were measured and the arithmetic average value was set as the excitation purity Pe (%) of the light emitting device of each of the Example 1 and Comparative Example 1.

Excitation Purity Pe (%) of each of the light emitting devices of Example 2 and Comparative Example 2 each having the dominant wavelength set to 612 nm was determined such that on JIS Z8701 chromaticity diagram, assuming a strain line passing through chromaticity point W (x_{w}=0.33333, y_{w}=0.33333) of white light and monochromatic stimulus S₂(xₛ₂=0.67186, yₛ₂=0.32795), a distance between the chromaticity point W and the chromaticity point F (chromaticity coordinates (x, y) of each light emitting device) and a distance between the chromaticity point W and the monochromatic stimulus S₂ were measured, and a ratio WF/WS₂ was determined as excitation purity (%). More specifically, excitation purity Pe (%) often light emitting devices of each of Example 2 and Comparative Example 2 were measured and the arithmetic average value was set as the excitation purity Pe (%) of the light emitting device of each of the Example 2 and Comparative Example 2.

Luminous intensity Ratio Ir

In the emission spectrum of each of the light emitting device of Examples and Comparative Examples, a luminous intensity ratio Ir of the luminous intensity of the peak emission wavelength of the light emitting element in a range of 365 to 500 nm with respect to the maximum luminous intensity of the light emitting device was determined. More specifically, luminous intensity ratios Ir of ten light emitting devices of each of Examples and Comparative Examples were measured and the arithmetic average value was set as the luminous intensity ratio of the light emitting device of each of the Examples and Comparative Examples.

### Relative Luminous Flux (%)

Of the light emitting devices of Examples and Comparative Examples, the light emitting devices exhibited the excitation purity of 99.0% or greater, total luminous flux was measured using a total luminous flux measurement device using an integrating sphere. The total luminous flux of the light emitting device of Example 1 is a value relative to the total luminous flux of the light emitting device as 100%, in which, the fluorescent material used in the light emitting device of Comparative Example 1 was used in the light emitting device and he light emitting devices exhibited the excitation purity of 99.0%. The total luminous flux of the light emitting device of Example 2 is a value relative to the total luminous flux of the light emitting device as 100%, in which, the fluorescent material used in the light emitting device of Comparative Example 2 was used in the light emitting device and he light emitting devices exhibited the excitation purity of 99.0%. The light emitting devices of Examples 1 and 2 can emit red light with high excitation purity similar to a monochromatic excitation impurity 99.0% or greater.

TABLE 3

| | Fluorescent material | | | | | | Luminous intensity | |
|---|---|---|---|---|---|---|---|---|
| | | Content | Chromaticity | | Dominant | Excitation | ratio of light | Relative |
| | | (parts | coordinates | | wavelength | purity | emitting element Ir | luminous flux |
| | Type | mass) | x | y | (nm) | (%) | (%) | (%) |
| Comparative | Fluorescent | 40 | 0.667 | 0.321 | 615 | 96.3 | 1.21 | 100.0 |
| example 1 | material 1 | | | | | | | |
| Example 1 | Fluorescent | 120 | 0.667 | 0.321 | 615 | 99.3 | 0.09 | 105.9 |
| Comparative | material 2 | 70 | 0.664 | 0.328 | 612 | 97.4 | 0.85 | 100.0 |
| example 2 | | | | | | | | |
| Example 2 | Fluorescent | 120 | 0.664 | 0.332 | 611 | 99.1 | 0.18 | 102.5 |
| | Material 3 | | | | | | | |

The light emitting devices of Examples 1 and 2 emitted red light with a high excitation purity of 99.0% or greater. From each of the light emitting devices of Examples 1 and 2, the luminous intensity ratio Ir of light emitted from the light emitting element at the peak emission wavelength in a range of 365 to 500 nm relative to the maximum emission intensity of the light emitting device is less than 0.2%. Thus, leakage of light emitted from the light emitting device from the light emitting device was reduced and light of high excitation purity was emitted from the light emitting device. The light emitting device of Example 2 emitted light with high excitation purity of 99.0% or greater and with higher luminous flux compared to the light emitting device of Comparative Example 2 configured to have the same dominant wavelength of 612 nm.

The light emitting device of Comparative Example 1 was configured such that the peak emission wavelength of the fluorescent material 1 contained in the fluorescent member is located at longer wavelength side compared to that of the fluorescent material 2 and the fluorescent material 3 and the light emitting device emits light having an object dominant wavelength of 615 nm, and accordingly the fluorescent material 1 contained in the fluorescent member was less than 115 parts mass relative to 100 parts mass of the resin, which resulted in a low excitation purity of less than 99.0%. Also, the light emitting device of Comparative Example 1 exhibited a high luminous intensity ratio Ir of greater than 0.2%, which indicates a greater amount of blue light emitted from the light emitting element was leaked out of the light emitting device.

Although including the fluorescent material 2 in the fluorescent member as in Example 1, the light emitting device of Comparative Example 2 was configured to emit light with a dominant wavelength of 612 nm, such that the fluorescent material 2 contained in the fluorescent member was less than 115 parts mass relative to 100 parts mass of the resin, which resulted in a low excitation purity of less than 99.0%. Also, the light emitting device of Comparative Example 2 exhibited a high luminous intensity ratio Ir of greater than 0.2%, which indicates a greater amount of blue light emitted from the light emitting element was leaked out of the light emitting device.

### Evaluation 2 of Light Emitting Device

The light emitting devices of Examples and Comparative Examples were further evaluated as described below. The results are shown in Table 4.

Wavelength Difference λe_{P}−λf_{P} (=Δλ_{P})

From the emission spectrum of each of the light emitting devices and the emission spectrum of each of the fluorescent material used in the corresponding light emitting devices, a wavelength difference λe_{P}−λf_{P} is (=Δλ_{P}) of the peak emission wavelength λe_{P} of the light emitting device and the peak emission wavelength λf_{P} of the fluorescent material was determined. More specifically, the peak emission wavelength λe_{P} of each of the light emitting devices was determined from the emission spectrum of each of the light emitting devices with the maximum emission intensity set to 100%. The peak emission wavelength λf_{P} of each of the fluorescent materials was determined from the emission spectrum of a single particle of the corresponding fluorescent material with the maximum emission intensity set to 100%.

Wavelength Difference λe_{S}−λf_{S} (=Δλ_{S}) at Luminous Intensity 10% at Shorter Wavelength Side

When the maximum emission intensity in the emission spectrum of each of the light emitting device is set to 100%, the wavelength at emission intensity 10% located at shorter wavelength side to the peak emission wavelength of the light emitting device is indicated as λe_{S} and the maximum emission intensity in the emission spectrum of each of the fluorescent materials is set to 100%, the wavelength at emission intensity 10% located at shorter wavelength side with respect to the peak emission wavelength of the fluorescent material is indicated as λf_{S}, a wavelength difference λe_{S}−λf_{S} (=Δλ_{S}) was determined.

Wavelength Difference λe_{L}−λf_{L} (=Δλ_{L}) at Luminous Intensity 10% at Longer Wavelength Side

When the maximum emission intensity in the emission spectrum of each of the light emitting device is set to 100%, the wavelength at emission intensity 10% located at longer wavelength side to the peak emission wavelength of the light emitting device is indicated as λe_{L} and the maximum emission intensity in the emission spectrum of each of the fluorescent materials is set to 100%, the wavelength at emission intensity 10% located at longer wavelength side to the peak emission wavelength of the fluorescent material is indicated as λf_{L}, a wavelength difference λe_{L}−λf_{L} (=Δλ_{L}) was determined.

### Thickness of Deposited Layer, Thickness of Fluorescent Member, Ratio of Thicknesses

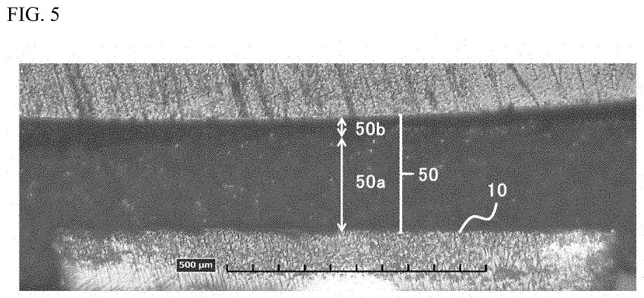

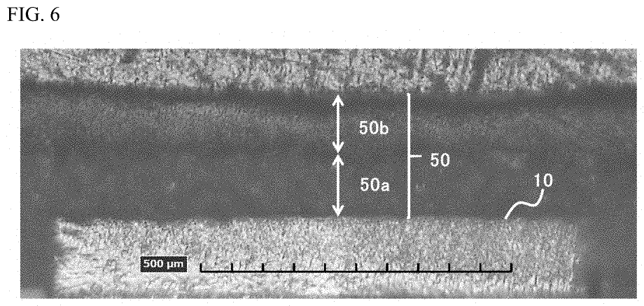

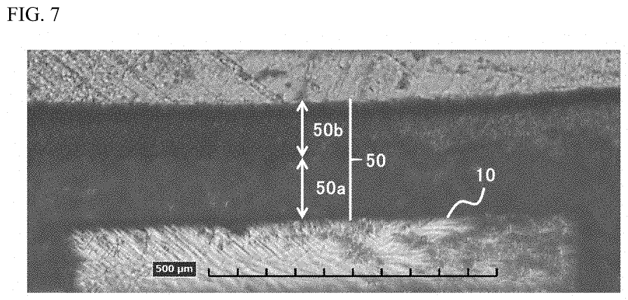

One light emitting device was respectively taken from the light emitting devices of Example 1, Example 2, and Comparative Example 1, and cut along a straight line passing through a center point in a plan view of each of the light emitting devices. Images of the cross sections were taken using a scanning electron microscope (SEM) and the SEM photographs of the cross-section of the light emitting devices were obtained. FIG. 5 is a SEM image showing a portion of cross-section of a light emitting device according to Example 1, FIG. 6 is a SEM image showing a portion of cross-section of a light emitting device according to Comparative Example 1, and FIG. 7 is a SEM image showing a portion of cross-section of a light emitting device according to Comparative Example 2. Thicknesses of the deposited layer (first layer 50a) and the resin layer (second layer 50b) directly above the light emitting element 10 on the respective photographs were measured. In the SEM images of the cross-sections of the light emitting devices, a thickness of the portions showing the presence of the fluorescent material was determined as the thickness of the deposited layer and a thickness of a portion showing absence of the fluorescent material was determined as the thickness of the resin layer, and the sum of the thicknesses of the deposited layer and the resin layer was determined as the thickness of the fluorescent member. The thickness of the deposited layer (first layer 50a) was measured, assuming a straight line perpendicular to a lower surface of the molded body, as a distance along the straight line from an intersection point of the straight line and an upper surface of the light emitting element 10 to an intersection point of the straight line and an interface between the deposited layer (first layer 50a) of the fluorescent material 70 and the resin layer (50b) in the fluorescent member 50. The thickness of the resin layer (second layer 50b) was measured as a distance along the straight line from an intersection point of the straight line and the interface between the deposited layer (first layer 50a) and the resin layer (50b) to the upper surface of the fluorescent member 50. The measurement of the thickness on each of the SEM images of the cross section of the light emitting devices was performed along an appropriately assumed single straight line perpendicular to the lower surface of the molded body 40. Using the measured thicknesses, the ratio Tr (thickness of deposited layer (first layer 50a)/thickness of fluorescent member 50) directly above the light emitting element 10 was calculated.

TABLE 4

| | | Wavelength difference at | | | | |
|---|---|---|---|---|---|---|
| | | 10% luminous intensity | | | | |
| | Wavelength | Short | Long wavelength | | | |
| | difference | wavelength side | side | | Fluorescent | |
| | λe_{P} − λf_{P} | λe_{S} − λf_{S} | λe_{L} − λf_{L} | Deposited layer | member | Thickness |
| | (= Δλ_{P}) | (= Δλ_{S}) | (= Δλ_{L} | Thickness | Thickness | ratio Tr |
| | (nm) | (nm) | (nm) | (μm) | (μm) | (%) |
| Comparative | 7.4 | 7.3 | 1.4 | 108 | 204 | 53 |
| example 1 | | | | | | |
| Example 1 | 9.4 | 13.3 | 0.9 | 194 | 223 | 87 |
| Comparative | 5.7 | 8.0 | 2.4 | 100 | 199 | 50 |
| example 2 | | | | | | |
| Example 2 | 8.3 | 11.3 | 0.5 | 160 | 190 | 84 |

The light emitting devices of Examples 1 and 2 have the wavelength difference Δλ_{P} greater than 8 nm, and the wavelength differences Δλ_{P} and Δλ_{S} greater than that of Comparative Examples, such that red light with high excitation purities can be emitted. Even with high excitation purities, the light emitting devices of Examples 1 and 2 have the wavelength difference Δλ_{L} smaller than that of Comparative Examples, such that emission intensities of the emission spectra at longer wavelength side with a low intensity human visibility can be reduced and light of high luminous flux can be emitted from the light emitting devices.

The light emitting device of Example 1 has a wavelength difference Δλ_{S} at lower wavelength side greater than that of the light emitting device of Comparative Example 2 that uses the same fluorescent material 2. Accordingly, as shown in FIG. 3, the emission spectrum of light emitting device of Example 1 at short wavelength side with respect to the peak emission wavelength overlap with a portion of the emission spectrum of the light emitting device of Comparative Example 1 into a similar shape. From these results, when the light emitting device of Example 1 is formed with the fluorescent material 2 that is used in the light emitting device of Comparative Example 1 having a peak emission wavelength located at shorter wavelength side than the peak emission wavelength of the fluorescent material 1, and increase the amount of the fluorescent material 2 in the fluorescent member, and the dominant wavelength is set to 615 nm as that of Comparative Example 1, red light with high excitation purity can be emitted.

The light emitting device of Example 2 has a wavelength difference Δλ_{S} at lower wavelength side greater than that of the light emitting device of Comparative Example 2. Accordingly, as shown in FIG. 4, the emission spectrum of light emitting device of Example 2 at shorter wavelength side to the peak emission wavelength overlap with a portion of the emission spectrum of the light emitting device of Comparative Example 2 into a similar shape. From these results, when the light emitting device of Example 2 is formed with the fluorescent material 3 that is used in the light emitting device of Comparative Example 2 having a peak emission wavelength located at shorter wavelength side than the peak emission wavelength of the fluorescent material 2, and increase the amount of the fluorescent material 3 in the fluorescent member, and the dominant wavelength is set to 612 nm as that of Comparative Example 2, red light with high excitation purity can be emitted.

In the reflection spectra of the fluorescent materials 1 to 3 shown in FIG. 2, the reflectance decrease (that is, absorptance increase) at shorter wavelength side to the peak emission wavelengths of the light emitting devices respectively using the fluorescent materials. The greater the content of the fluorescent material in the fluorescent member, the more self absorption between the fluorescent material particles, resulting in a decrease in emission intensity at shorter wavelength side of each of the emission spectra.

As shown in FIG. 5, in the SEM image of the cross section of the light emitting device according to Example 1, the thickness ratio Tr of the deposited layer (first layer 50a) containing the fluorescent material 1 to the thickness of the fluorescent member 50 is 87%, which indicates greater thickness of the deposited layer. Meanwhile, as shown in FIG. 6 and FIG. 7, in the SEM images of the cross section of the light emitting devices according to Comparative Example 1 and Comparative Example 2, the thickness ratios Tr of the deposited layers (first layers 50a) containing the fluorescent material 1 to the thickness of the fluorescent member 50 were respectively low values of 53% and 50%.

It is generally thought that with a smaller content of the fluorescent material in the fluorescent member and with a smaller thickness of the deposited layer (first layer 50a) containing the fluorescent member, scattering loss can be decreased, allowing an increase in the light emitting efficiency of the light emitting device. Meanwhile, the content of the fluorescent member in the fluorescent member decreased, resulting in a low excitation purity of the light emitting device. The light emitting device according to one embodiment of the present disclosure includes a greater amount of the fluorescent material having a peak emission wavelength at shorter wavelength side to obtain a desired shape of the emission spectrum of light emitted from the light emitting device, such that red light of high luminous flux and excitation purity can be obtained.

The light emitting device according to embodiments of the present invention can be suitably used in applications such as vehicle stop lamps, light source for general lighting, backlight light sources, light sources of displays, warning lights, and light sources for raising plant.

It is to be understood that although the present invention has been described with regard to preferred embodiments thereof, various other embodiments and variants may occur to those skilled in the art, which are within the scope and spirit of the invention, and such other embodiments and variants are intended to be covered by the following claims

What is claimed is:

1. A light emitting device comprising:
a light emitting element that emits light having a peak emission wavelength in a range of 365 to 500 nm;
a fluorescent member comprising a resin and a fluorescent material configured to be excited by the light from the light emitting element to emit light having a peak emission wavelength in a range of 620 to 670 nm, the fluorescent material having a composition represented by formula (I):
CaₛSrₜEuᵤSiᵥAl_{w}Nₓ (I)
wherein s, t, u, v, w, and x respectively satisfy 0.05≤s≤0.995, 0≤t≤0.95, 0.005≤u≤0.04, 0.8≤s+t+u≤1.1, 0.8≤v≤1.2, 0.8≤w≤1.2, 1.8≤v+w≤2.2, and 2.5≤x≤3.2,
wherein a content of the fluorescent material is in a range of 115 to 150 parts. mass relative to 100 parts mass of the resin, and
wherein the light emitting device is configured to emit light having a dominant wavelength in a range of 610 to 630 nm.

2. A light emitting device comprising:
a light emitting element that emits light having a peak emission wavelength in a range of 365 to 500 nm; and
a fluorescent member containing a fluorescent material configured to be excited by light from the light emitting element to emit light having a peak emission wavelength in a range of 620 to 670 nm;
the fluorescent material having a composition represented by the formula (I):
CaₛSrₜEuᵤSiᵥAl_{w}Nₓ (I)
wherein, s, t, u, v, w, and x respectively satisfy 0.05≤s≤0.995, 0≤t≤0.95, 0.005≤u≤0.04, 0.8≤s+t+u≤1.1, 0.8≤v≤1.2, 0.8≤w≤1.2, 1.8≤v+w≤2.2, and 2.5≤x≤3.2,
wherein when a peak emission wavelength in an emission spectrum of the light emitting device is indicated as λe_{P} and a peak emission wavelength in an emission spectrum of the fluorescent material is indicated by λf_{P}, a wavelength difference λe_{P}−λf_{P} is 8 nm or greater, and
wherein light emitted from the light emitting device has a dominant wavelength in a range of 610 to 630 nm.

3. The light emitting device according to claim 1, configured to emit light with an excitation purity calculated on a JIS Z8701 chromaticity diagram of 99% or greater.

4. The light emitting device according to claim 2, configured to emit light with an excitation purity calculated on a JIS Z8701 chromaticity diagram of 99% or greater.

5. The light emitting device according to claim 1, wherein in the formula (I), s, t, and u respectively satisfy 0.1≤s≤0.3, 0.7≤t≤0.95, and 0.01≤u≤0.03.

6. The light emitting device according to claim 2, wherein in the formula (I), s, t, and u respectively satisfy 0.1≤s≤0.3, 0.7≤t≤0.95, and 0.01≤u≤0.03.

7. The light emitting device according to claim 1, wherein in the fluorescent member, a content of the fluorescent material is in a range of 120 to 145 parts mass relative to 100 parts mass of the resin.

8. The light emitting device according to claim 1, wherein the fluorescent material has a reflectance of 20% or less at a wavelength of 450 nm.

9. The light emitting device according to claim 2, wherein the fluorescent material has a reflectance of 20% or less at a wavelength of 450 nm.

10. The light emitting device according to claim 1, wherein when a peak emission wavelength of an emission spectrum of the light emitting device is indicated by λeP and an peak emission wavelength of an emission spectrum of the fluorescent material is indicated by λfP, a wavelength difference λe_{P}−λf_{P} is 8 nm or greater.

11. The light emitting device according to claim 1, wherein the light emitting element has a luminous intensity at its peak emission wavelength less than 0.2% with respect to a maximum luminous intensity of the light emitting device.

12. The light emitting device according to claim 2, wherein the light emitting element has a luminous intensity at its peak emission wavelength less than 0.2% with respect to a maximum luminous intensity of the light emitting device.

13. The light emitting device according to claim 1, wherein when a maximum emission intensity in an emission spectrum of the light emitting device is set to 100%, a wavelength at emission intensity 10% located at a shorter wavelength side with respect to a peak emission wavelength of the light emitting device is indicated as λe_{S}, and a maximum emission intensity in an emission spectrum of the fluorescent material is set to 100%, a wavelength at emission intensity 10% located at a shorter wavelength side with respect to a peak emission wavelength of the fluorescent material is indicated as λf_{S}, a wavelength difference λe_{S}−λf_{S} is 8.5 nm or greater.

14. The light emitting device according to claim 2, wherein when a maximum emission intensity in an emission spectrum of the light emitting device is set to 100%, a wavelength at emission intensity 10% located at a shorter wavelength side with respect to a peak emission wavelength of the light emitting device is indicated as λe_{S}, and a maximum emission intensity in an emission spectrum of the fluorescent material is set to 100%, a wavelength at emission intensity 10% located at a shorter wavelength side with respect to a peak emission wavelength of the fluorescent material is indicated as λf_{S}, a wavelength difference λe_{S}−λf_{S} is 8.5 nm or greater.

15. The light emitting device according to claim 1, wherein when a maximum emission intensity in an emission spectrum of the light emitting device is set to 100%, a wavelength at emission intensity 10% located at a longer wavelength side to a peak emission wavelength of the light emitting device is indicated as λe_{L} and a maximum emission intensity in an emission spectrum of the fluorescent material is set to 100%, a wavelength at emission intensity 10% located at a longer wavelength side with respect to a peak emission wavelength of the fluorescent material is indicated as λf_{L}, a wavelength difference λe_{L}−λf_{L} is 1.2 nm or less.

16. The light emitting device according to claim 2, wherein when a maximum emission intensity in an emission spectrum of the light emitting device is set to 100%, a wavelength at emission intensity 10% located at a longer wavelength side with respect to a peak emission wavelength of the light emitting device is indicated as λe_{L} and a maximum emission intensity in an emission spectrum of the fluorescent material is set to 100%, a wavelength at emission intensity 10% located at a longer wavelength side with respect to a peak emission wavelength of the fluorescent material is indicated as λf_{L}, a wavelength difference λe_{L}−λf_{L} is 1.2 nm or less.

17. A method of manufacturing a light emitting device configured to emit light having a dominant wavelength in a range of 610 to 630 nm, the method comprising:
disposing a light emitting element that emits light having a peak emission wavelength in a range of 365 to 500 nm on a support member;
providing a fluorescent material and a resin, the fluorescent material having a composition represented by a formula (I) and configured to be excited by the light from the light emitting element to emit light having a peak emission wavelength in a range of 620 to 670 nm;
CaₛSrₜEuᵤSiᵥAl_{w}Nₓ (I)
where s, t, u, v, w, and x respectively satisfy 0.05≤s≤0.995, 0≤t≤0.95, 0.005≤u≤0.04, 0.8≤s+t+u≤1.1, 0.8≤v≤1.2, 0.8≤w≤1.2, 1.8≤v+w≤2.2, and 2.5≤x≤3.2,
mixing the fluorescent material and the resin such that a content of the fluorescent material is in a range of 115 to 150 parts by mass relative to 100 parts by mass of the resin to obtain a composition for fluorescent member; and
disposing the composition for fluorescent member on the light emitting element to obtain a fluorescent member.

18. The method of manufacturing a light emitting device according to claim 17, wherein in the formula (I), s, t, and u respectively satisfy 0.1≤s≤0.3, 0.7≤t≤0.95, and 0.01≤u≤0.03.

19. The method of manufacturing a light emitting device according to claim 17, wherein the content of the fluorescent material relative to 100 parts mass of the resin is in a range of 120 to 145 parts mass.

20. The method of manufacturing a light emitting device according to claim 17, wherein when a peak emission wavelength of an emission spectrum of the light emitting device is indicated by λeP and a peak emission wavelength of an emission spectrum of the fluorescent material is indicated by λfP, a wavelength difference λeP−λfP is 8 nm or greater.
